(19) United States
(12) Patent Application Publication
(10) Pub. No.: US 2009/0020845 A1
(43) Pub. Date: Jan. 22, 2009

(54) SHALLOW TRENCH ISOLATION STRUCTURES FOR SEMICONDUCTOR DEVICES INCLUDING DOPED OXIDE FILM LINERS AND METHODS OF MANUFACTURING THE SAME

(75) Inventors: Dong-suk Shin, Gyeonggi-do (KR); Moon-han Park, Gyeonggi-do (KR); Joo-won Lee, Gyeonggi-do (KR); Jae-yoon Yoo, Seoul (KR); Tae-gyun Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/106,671

(22) Filed: Apr. 21, 2008

(30) Foreign Application Priority Data
Jul. 16, 2007 (KR) 10-2007-0071277

(51) Int. Cl. H01L 21/762; H01L 23/00

(52) U.S. Cl. 257/506; 438/425; 257/E23.002; 257/E21.546

(57) ABSTRACT

A semiconductor device includes a substrate having a trench, a sidewall liner that covers inner walls of the trench, a doped oxide film liner on the sidewall liner in the trench, and a gap-fill insulating film that buries the trench on the doped oxide film liner. In order to form the doped oxide film liner, an oxide film liner is doped with a dopant under a plasma atmosphere. Related methods are also disclosed.

### CROSS-REFERENCE TO RELATED PATENT APPLICATION

This application claims priority under 35 USC §119 to Korean Patent Application No. 10-2007-0071277, filed on Jul. 16, 2007, the disclosure of which is hereby incorporated herein by reference in its entirety as if set forth fully herein.

### FIELD OF THE INVENTION

The present invention relates to semiconductor integrated circuit devices and methods of manufacturing the same, and more particularly, to semiconductor devices having shallow trench isolation (STI) structures and methods of manufacturing the same.

### BACKGROUND OF THE INVENTION

As the integration density of semiconductor (i.e., integrated circuit) devices increases, the importance of device isolation techniques for electrically isolating adjacent devices may further increase. In a manufacturing process of highly integrated semiconductor devices, a shallow trench isolation (STI) structure forming process is widely employed as a device isolation technique. Due to the development of various scaling techniques for manufacturing highly integrated semiconductor devices and as the feature sizes of semiconductor devices are reduced to, for example, 45 nm or less, the difficulty of forming the STI structure for separating the semiconductor devices may further increase.

Various device isolation processes that use the STI structure have been proposed. In one process, a substrate is trenched using a nitride film pattern formed in the substrate as an etch mask, a nitride film liner is formed in the trench and a device isolation film is formed by filling an insulating material on the nitride film liner. Afterwards, a wet etching process is performed to remove the nitride film pattern on the substrate. At this point, in many cases, a dent may be formed near an upper edge (i.e., opening) of the trench due to consumption by etching the nitride film liner exposed near the edge portion on the trench to a predetermined depth from the upper surface of the substrate. This may cause various degradations of the semiconductor device.

Even when the nitride film liner that causes the formation of a dent in the trench is not formed, there is a possibility that a recess that exposes a sidewall of an active region near an inlet (i.e., opening or entry) edge of the trench can be formed through a cleaning process and/or an oxide film etching process, which are used in a semiconductor device manufacturing process. When a semiconductor device is manufactured in which the recess that exposes a sidewall of an active region is formed, the recess may increase junction leakage current in the active region, and thus, the electrical characteristics of the semiconductor device may be degraded.

### SUMMARY OF THE INVENTION

According to some embodiments of the present invention, a semiconductor device includes a substrate having a trench therein, a sidewall liner on inner walls of the trench, a doped oxide film liner on the sidewall liner in the trench, and a gap-fill insulating film on the doped oxide film liner. In some embodiments, the sidewall liner is directly on the inner walls of the trench, the doped oxide film liner is directly on the sidewall liner and the gap-fill insulating film is directly on the doped oxide film liner. The doped oxide film liner may consist of an oxide film doped with N atoms.

According to other embodiments of the present invention, methods of manufacturing a semiconductor device are provided. These methods include forming a trench in a substrate, forming a sidewall liner on inner walls of the trench, forming a doped oxide film liner on the sidewall liner in the trench, and forming a gap-fill insulating film on the doped oxide film liner. In some embodiments, the sidewall liner is formed directly on the inner walls of the trench, the doped oxide film liner is formed directly on the sidewall liner, and the gap-fill insulating film is formed directly on the doped oxide film liner.

The sidewall liner may be fabricated by nitrating the inner walls of the trench, and forming an SiON liner by oxidizing the nitrated inner walls of the trench.

The doped oxide film liner may be formed by forming an oxide liner on the sidewall liner, and plasma treating the oxide liner under a gas atmosphere that comprises N₂ gas.

The methods may further comprise performing a densification process to densify the oxide film liner by exposing the oxide film liner in an oxidizing gas atmosphere after forming the oxide film liner.

The methods may further comprise performing a densification process to densify the doped oxide film liner by exposing the doped oxide film liner in an oxidizing gas atmosphere after forming the doped oxide film liner.

Semiconductor devices according to some embodiments of the present invention can have a shallow trench isolation (STI) structure in which an oxide film liner doped with a dopant is formed. The oxide film liner doped with a dopant can have high etching resistance with respect to an etchant and/or a cleaning solution. Thus, after the STI structure is formed, during subsequent semiconductor manufacturing process, such as a series of processes for forming transistors and/or source/drain regions, the oxide film doped with a dopant is often exposed to multiple cleaning and etching processes. However, due to the etching resistance of the oxide film, the consumption of the device isolation film near an inlet edge portion of the trench may be reduced or prevented. Thus, the formation of a recess that exposes a sidewall of the active region near the inlet edge portion of the trench can be reduced or prevented. Therefore, according to some embodiments of the present invention, device failure or electrical characteristic degradation of a semiconductor device due to recess at an inlet portion of a trench can be effectively reduced or prevented.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1J are cross-sectional views illustrating methods of manufacturing semiconductor devices according to various embodiments of the present invention, and devices so manufactured.

### DETAILED DESCRIPTION OF THE INVENTION

The present invention is described more fully hereinafter with reference to the accompanying drawings, in which embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components. The terms “opening”, “entry”, “entrance” and “inlet” are used synonymously herein to refer to the region of the trench that is remote from the trench bottom or floor.

Embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

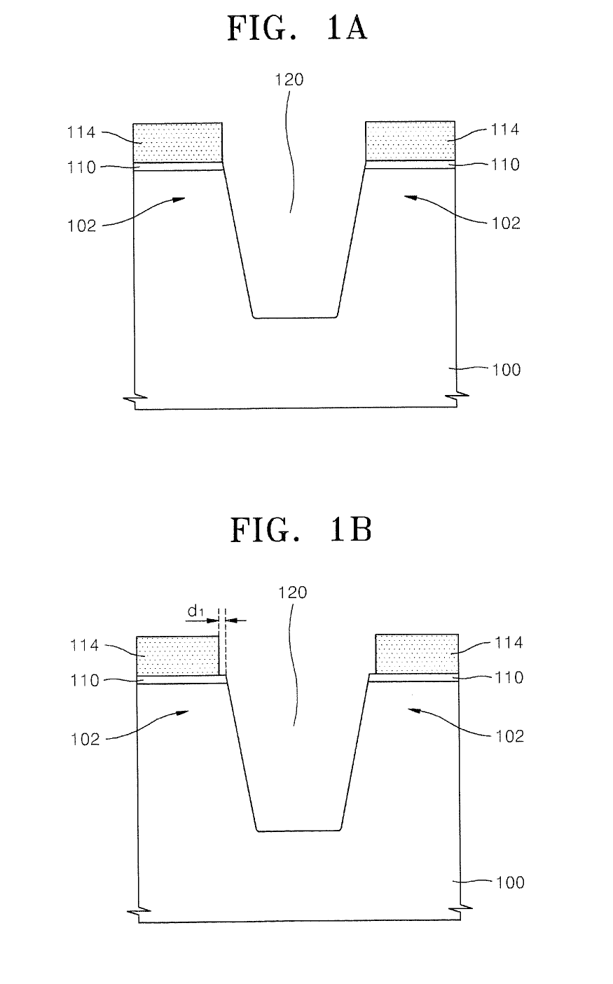

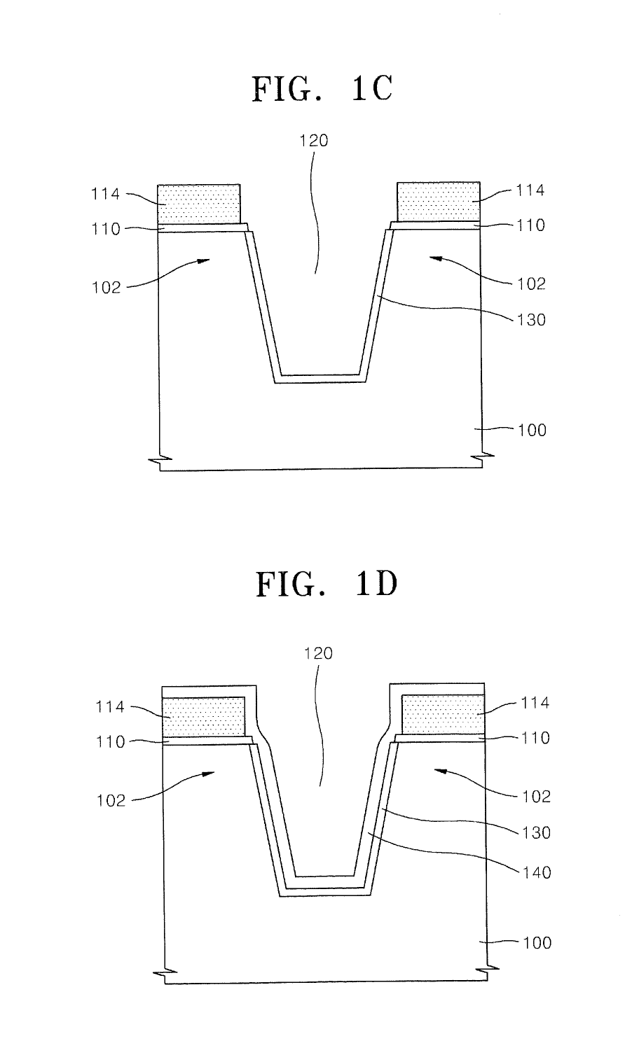

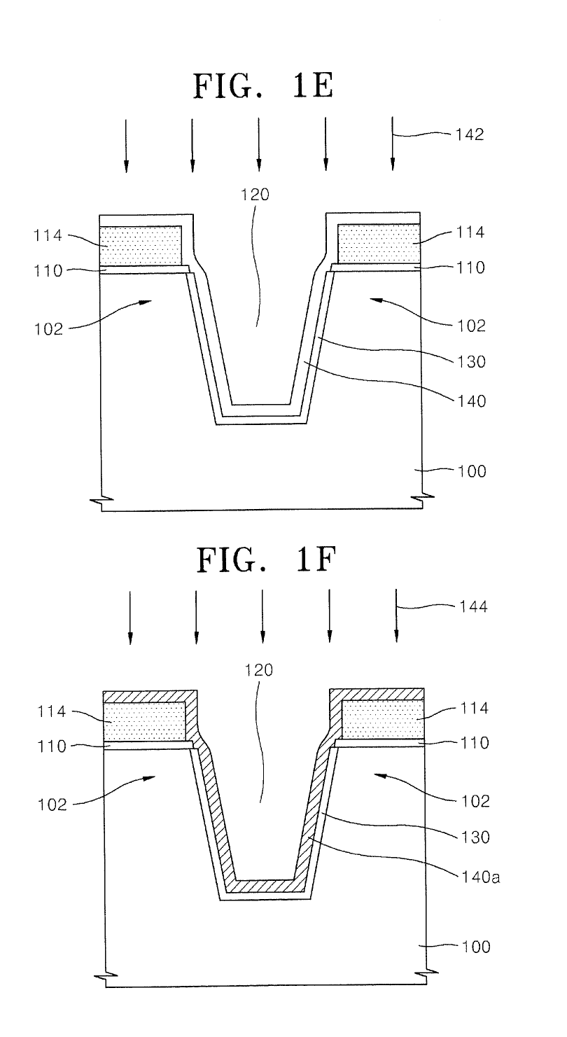

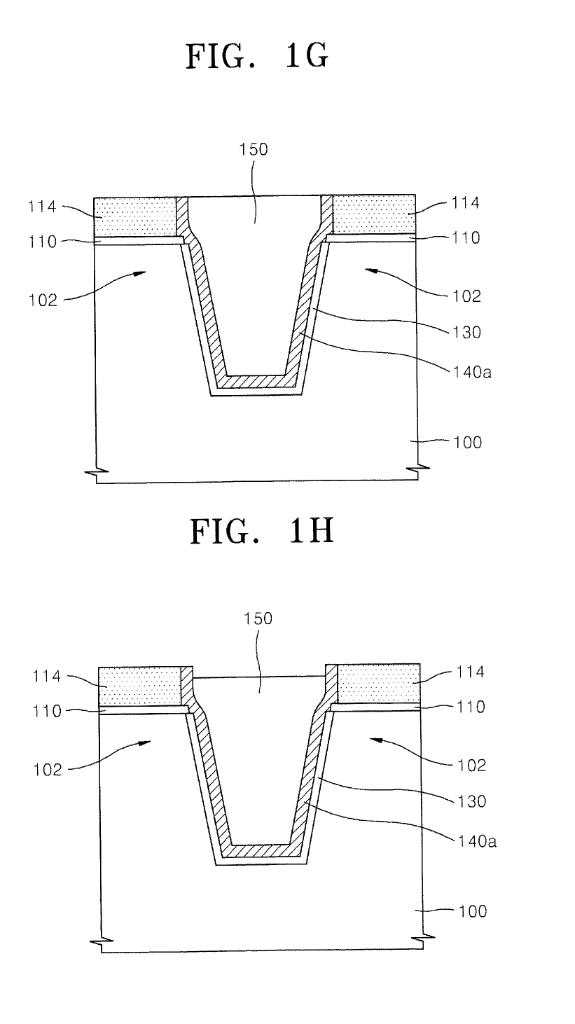

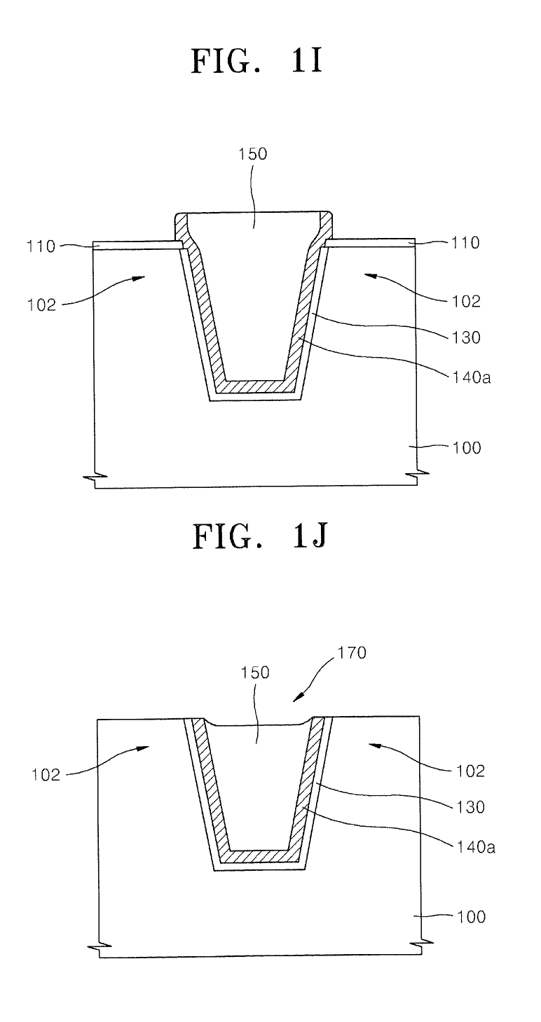

FIGS. 1A through 1J are cross-sectional views illustrating methods of manufacturing semiconductor devices according to various embodiments of the present invention, and devices so manufactured.

Referring to FIG. 1A, a pad oxide film and a nitride film are sequentially formed on an upper surface of a semiconductor (i.e., integrated circuit) substrate 100, for example, a silicon substrate. For example, the pad oxide film can be formed to a thickness of about 50 Å to about 150 Å using a thermal oxidation process. The nitride film can be a silicon nitride film formed to a thickness of about 1200 Å to about 1600 Å using chemical vapour deposition (CVD) process. Afterwards, a pad oxide film pattern 110 and a nitride film pattern 114 that expose a device isolation region of the semiconductor substrate 100 are formed by patterning the nitride film and the pad oxide film using a photolithography method.

Next, a trench 120 that defines an active region 102 in the semiconductor substrate 100 is formed by dry etching the exposed semiconductor substrate 100 to a predetermined depth using the pad oxide film pattern 110 and the nitride film pattern 114 as etch masks. The trench 120 can be formed to have a depth of about 250 nm to about 350 nm.

Referring to FIG. 1B, a predetermined thickness of the nitride film pattern 114 is removed using an isotropic etching process. That is, a pullback process of the nitride film pattern 114 is performed so that the nitride film pattern 114 does not cover an inlet of the trench 120. In order to perform the pullback process, a strip process can be performed with respect to the nitride film pattern 114 using a phosphoric acid solution. Due to the pullback process, edges of sidewalls of the nitride film pattern 114 can be pulled back by a predetermined distance d₁ from the inlet of the trench 120.

Referring to FIG. 1C, a sidewall liner 130 is formed on an inner wall of the trench 120 and, in some embodiments, directly on the inner wall of the trench 120. The sidewall liner 130 can be formed to cover the inner wall of the trench 120 and the sidewall liner 130 can contact the active region 102. The sidewall liner 130 can be formed of, for example, SiON. However, embodiments of the present invention are not limited thereto. That is, the sidewall liner 130 can be formed of various kinds of insulation films, such as an oxide film and/or a nitride film, within the scope of the present invention.

When the sidewall liner 130 is formed of SiON, in order to form the sidewall liner 130, a surface of the silicon substrate exposed on the inner wall of the trench 120 may be nitrated under an NH₃ gas atmosphere, and then successively oxidized under an O₂ gas atmosphere. Thus, the SiON liner may be formed by nitrating and oxidizing a portion of the surface of the silicon substrate exposed on the inner wall of the trench 120. The sidewall liner 130 can be formed to a thickness of, for example, about 1 nm to about 10 nm.

The sidewall liner 130 can reduce or prevent the curing of a surface of the semiconductor substrate 100 damaged during a dry etching for forming the trench 120. Thus, a current leakage that can be caused due to the damaged semiconductor substrate 100 can be reduced or prevented. Also, as the thickness of the sidewall liner 130 is increased, an edge portion of the trench 120 can be rounded.

Referring to FIG. 1D, an oxide film liner 140 is formed on the sidewall liner 130, and, in some embodiments, directly on the sidewall liner 130. The oxide film liner 140 can be formed of a silicon oxide film to a thickness of about 5 nm to about 20 nm. In order to form the oxide film liner 140, a middle temperature oxide (MTO) deposition process can be performed at a temperature of, for example, about 600° C. to 800° C.

Referring to FIG. 1E, a densification of the oxide film liner 140 is performed by exposing the oxide film liner 140 in an oxide gas atmosphere 142, for example, an O₂ gas atmosphere at a temperature of about 800° C. to about 1000° C.

The densification process described with reference to FIG. 1E using the O₂ gas 142 may not be needed and, thus, it can be omitted in some embodiments.

Referring to FIG. 1F, a doped oxide film liner 140a is formed by doping a dopant 144 in the oxide film liner 140.

The doped oxide film liner 140a can provide a high etching resistance with respect to an etchant for removing an oxide film and/or a cleaning solution. Thus, the etching resistance of the doped oxide film liner 140a reduces or prevents the doped oxide film liner 140a and the sidewall liner 130 that is covered by the doped oxide film liner 140a from being consumed due to the etchant or the cleaning solution even though the STI structure in the trench 120 is exposed to various cleaning processes. Also, in a subsequent process, when a well is formed by implanting a dopant into the active region 102 of the semiconductor substrate 100 defined by the trench 120, the doped oxide film liner 140a can reduce or prevent a dopant such as boron (B) from being diffused into the device isolation film in the trench 120.

In order to form the doped oxide film liner 140a, in some embodiments, an exposed surface of the oxide film liner 140 can be plasma treated under a nitrogen atmosphere. In this case, N atoms are doped on the exposed surface of the oxide film liner 140, and thus, the doped oxide film liner 140a doped with an N-doped oxide film is obtained. In some embodiments, the doped oxide film liner 140a can consist of a silicon oxide film doped with N atoms.

The plasma treatment for forming the doped oxide film liner 140a can be performed, for example, at a temperature of about 400° C. to about 800° C. under a gas atmosphere that includes N₂ gas. The plasma treatment can be performed under an atmosphere consisting of N₂ gas or under the atmosphere comprising a gas mixture in which the N₂ gas and at least one additive gas comprising H₂, O₂, He and/or Ar are mixed. When the gas mixture that includes the additive gas is used, the additive gas can be added to the gas mixture to approximately 50 volume % or less. In a particular embodiment, an RF power for the plasma treatment can be controlled to a range from about 400 W to about 1200 W. However, the power is not limited thereto, and a desired RF power can be applied to the plasma treatment according to various process conditions. In some cases, the plasma treatment process can be performed using a remote plasma method. Also, a bias power of about 100 W to about 500 W can be applied together with the RF power.

The concentration of the N atoms in the doped oxide film liner 140a can be, for example, in a range from about 1×10¹⁴ cm⁻³ to about 1×10¹⁶ cm⁻³.

The doped oxide film liner 140a formed according to the methods described above can provide a high etching resistance compared to a conventional oxide film when the doped oxide film liner 140a is exposed to an etchant for removing an oxide film.

Although not shown, after the doped oxide film liner 140a is formed according to the processes described with reference to FIG. 1F, a process for densifying the doped oxide film liner 140a can further be performed by exposing the doped oxide film liner 140a at a temperature of about 800° C. to about 1000° C. under an oxidation gas atmosphere 142 as described with reference to FIG. 1E. Through the densification of the doped oxide film liner 140a, the etching resistance of the doped oxide film liner 140a with respect to an etchant or a cleaning solution can further be increased.

Referring to FIG. 1G, an oxide film is deposited on, and in some embodiments directly on, the doped oxide film liner 140a, until the trench 120 is completely filled. Afterwards, the oxide film is densified through an annealing process, and then, a gap-fill insulating film 150 is formed in the trench by performing a chemical mechanical polishing (CMP) process and/or an etch-back process until the nitride film pattern 114 is exposed. For the densification of the oxide film, the oxide film can be annealed, for example, for approximately 1 hour at a relatively high temperature of about 900° C. to about 1050° C. in an N₂ atmosphere. Alternatively, for the densification of the oxide film, after annealing the oxide film, for example, for approximately 30 minutes at a relatively low temperature of approximately 700° C. under a steam atmosphere, the oxide film can then be annealed for approximately 1 hour at a relatively high temperature of about 900° C. to about 1050° C. under the N₂ atmosphere.

The gap-fill insulating film 150 can be formed of, for example, a high density plasma (HDP) oxide film, and alternatively, a CVD oxide film such as an undoped silicon glass (USG) or a tetraethyl orthosilicate (O₃-TEOS) film. In particular, if the gap-fill insulating film 150 is formed of the O₃-TEOS film, a semi-atmosphere chemical vapor deposition (SACVD) process can be used.

Referring to FIG. 1H, in order to reduce the possibility that an oxide film residue remains on the upper surface of the nitride film pattern 114, the resultant product on which the gap-fill insulating film 150 is formed is cleaned using an etchant that can selectively remove the oxide film. As a result, a top level of the gap-fill insulating film 150 is lowered faster than the top level of the nitride film pattern 114.

Referring to FIG. 1I, the nitride film pattern 114 which was used as a mask for forming the trench 120 is removed by a wet cleaning process that uses, for example, a phosphoric acid solution.

The doped oxide film liner 140a has a high etching resistance with respect to the etchant for removing the nitride film pattern 114. Thus, a portion of the doped oxide film liner 140a between the nitride film pattern 114 and the gap-fill insulating film 150 is not removed even though the nitride film pattern 114 is removed due to the wet cleaning process and remains in a state covering the sidewall of the gap-fill insulating film 150. Due to the portion of the doped oxide film liner 140a that covers the sidewall of the gap-fill insulating film 150, an inlet edge portion of the trench 120 is protected. Thus, the cleaning away of the device isolation films formed on the inlet edge of the trench 120 due to the cleaning solution or the etchant can be reduced or prevented.

As described with reference to FIG. 1F, if the gap-fill insulating film 150 is formed on the oxide film liner 140 without forming the doped oxide film liner 140a, a portion of the gap-fill insulating film 150 can also be removed together with the removal of pad oxide film pattern 110 through consecutive conventional cleaning processes. In this case, the top level of the gap-fill insulating film 150 can be reduced.

In particular, after depositing the insulating material in the trench 120 to form the device isolation film, the sidewall liner 130 and the oxide film liner 140 near the edge portion of the active region 102 of the semiconductor substrate 100 defined by the trench 120, can be physically degraded due to a physical stress caused during the annealing. When such physically degraded surfaces of the sidewall liner 130 and the oxide film liner 140 are exposed to various cleaning and etching processes in subsequent processes, the consumption of the sidewall liner 130 and the oxide film liner 140 may be increased. In this case, the top levels of the sidewall liner 130 and the oxide film liner 140 at the inlet edge portion of the trench 120 can be recessed to a level lower than the top level of the gap-fill insulating film 150. If the top levels of the sidewall liner 130 and the oxide film liner 140 are recessed as described above, when a metal silicide film is formed in source and drain regions (not shown) in the active region 102 defined by the trench 120 in a subsequent process, the metal silicide film can be formed on the sidewall of the active region 102 exposed through the recess in the trench 120, thereby increasing a junction leakage current.

According to methods of manufacturing semiconductor devices according to various embodiments of the present invention, an STI structure 170 that includes the doped oxide film liner 140a is formed as in the process described with reference to FIG. 1F. Thus, although a series of wet cleaning processes for cleaning or removing an oxide film are performed in subsequent processes, the consumption of the inlet edge portion of the trench 120, in particular, the sidewall liner 130 and the doped oxide film liner 140a, by the cleaning solution or the etchant, can be reduced or prevented. The formation of recess at the inlet edge of the trench 120 may be reduced or prevented. As a result, the increase in the junction leakage current in the active region 102 of the semiconductor substrate 100 may be reduced or prevented.

Referring to FIG. 1J, the pad oxide film pattern 110 that covers the upper surface of the semiconductor substrate 100 is removed.

After removing the pad oxide film pattern 110, source and drain regions (not shown) may be formed in the active region 102 of the semiconductor substrate 100, a gate insulating film (not shown), and a gate (not shown) may be formed using conventional methods of forming a transistor. A plurality of oxide film removing etching processes and/or cleaning processes can be performed during the series of processes for forming the transistor in the active region 102. At this point, the doped oxide film liner 140a is formed at the edge portion of the active region 102 at the inlet edge portion of the trench 120 in the STI structure 170 exposed on the semiconductor substrate 100. Accordingly, as depicted in FIG. 1J, although the doped oxide film liner 140a is exposed by consuming a predetermined thickness of the gap-fill insulating film 150, since the doped oxide film liner 140a has a high etching resistance with respect to the cleaning solution and/or the etchant for etching the oxide film, the consumption of the doped oxide film liner 140a and the sidewall liner 130 can be reduced or prevented. Thus, little or no recess is formed near inlet edge portion of the trench 120.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
a substrate having a trench therein;
a sidewall liner on inner walls of the trench;
a doped oxide film liner on the sidewall liner in the trench, remote from the inner walls of the trench; and
a gap-fill insulating film on the doped oxide film liner.

2. The semiconductor device of claim 1, wherein the doped oxide film liner consists of a silicon oxide film doped with N atoms.

3. The semiconductor device of claim 2, wherein a concentration of the N atoms in the doped oxide film liner is about 1×10¹⁴ cm⁻³ to about 1×10¹⁶ cm⁻³.

4. The semiconductor device of claim 1, wherein the sidewall liner comprises SiON.

5. The semiconductor device of claim 1, wherein the doped oxide film liner has a thickness in a range from about 5 nm to about 20 nm.

6. The semiconductor device of claim 1, wherein the sidewall liner is directly on the inner walls of the trench, the doped oxide film is directly on the sidewall liner and the gap-fill insulating film is directly on the doped oxide film liner.

7. A method of manufacturing a semiconductor device comprising:
forming a trench in a substrate;
forming a sidewall liner on inner walls of the trench;
forming a doped oxide film liner on the sidewall liner in the trench; and
forming a gap-fill insulating film on the doped oxide film liner.

8. The method of claim 7, wherein the sidewall liner comprises SiON.

9. The method of claim 8, wherein the forming of the sidewall liner comprises:
nitrating the inner walls of the trench; and
forming a SiON liner by oxidizing the nitrated inner walls of the trench.

10. The method of claim 7, wherein the doped oxide film liner consists of an oxide film doped with N atoms.

11. The method of claim 10, wherein a concentration of the N atoms in the doped oxide film liner is about 1×10¹⁴ cm⁻³ to about 1×10¹⁶ cm⁻³.

12. The method of claim 10, wherein the forming of the doped oxide film liner comprises:
forming an oxide liner on the sidewall liner; and
plasma treating the oxide liner under a gas atmosphere that comprises N₂ gas.

13. The method of claim 12, wherein the gas atmosphere that comprises N₂ gas consists of N₂ gas.

14. The method of claim 12, wherein the gas atmosphere that comprises N₂ gas comprises N₂ gas and at least one additive gas comprising H₂, O₂, He and/or Ar.

15. The method of claim 12, wherein the plasma treating is performed at a temperature of about 400° C. to 800° C.

16. The method of claim 12, wherein the oxide film liner is deposited at a temperature of about 600° C. to about 800° C. using a middle temperature oxide (MTO) deposition process.

17. The method of claim 12, wherein the oxide film liner comprises a silicon oxide film.

18. The method of claim 12, further comprising performing a densification process to densify the oxide film liner by exposing the oxide film liner in an oxidizing gas atmosphere after forming the oxide film liner.

19. The method of claim 18, wherein the densification process is performed at a temperature of about 800° C. to 1000° C.

20. The method of claim 7, further comprising performing a densification process to densify the doped oxide film liner by exposing the doped oxide film liner in an oxidizing gas atmosphere after forming the doped oxide film liner.

21. The method of claim 20, wherein the densification process is performed at a temperature of about 800° C. to about 1000°.

22. The method of claim 7, wherein the gap-fill insulating film comprises a tetraethyl orthosilicate (O₃-TEOS) film that is formed using a semi-atmosphere chemical vapor deposition (SACVD) process.

23. The method of claim 7 wherein the sidewall liner is formed directly on the inner walls of the trench, the doped oxide film liner is formed directly on the sidewall liner and the gap-fill insulating film is formed directly on the doped oxide film liner.
